(19) United States
(12) Patent Application Publication
(10) Pub. No.: US 2026/0181815 A1
(43) Pub. Date: Jun. 25, 2026

(54) Computer Chassis Power Supply Fan Device and Installation Method

(71) Applicant: Dongguan Chenjing Electronic Technology Co., Ltd., Dongguan City (CN)

(72) Inventors: Zhenhua Lin, Dongguan City (CN); Kaiming Cao, Dongguan City (CN); Qianyun Yu, Dongguan City (CN); Na Li, Dongguan City (CN)

(21) Appl. No.: 19/021,019

(22) Filed: Jan. 14, 2025

(30) Foreign Application Priority Data
Dec. 23, 2024 (CN) 2024119020617

(51) Int. Cl. H05K 7/20; G06F 1/20

(52) U.S. Cl. CPC H05K 7/20136; G06F 1/20

(57) ABSTRACT

A fan device for a computer chassis power supply comprises a power supply housing, a power supply body disposed, and a cooling fan. The power supply housing has an outer side surface formed with a slot for insertion and accommodation of the cooling fan. A housing positioning structure and a power supply electrode, electrically connected to the power supply body. The cooling fan includes a fan frame, fan blades pivotally connected to the fan frame, and a driving unit. The fan frame has a fan positioning structure that mates with the housing positioning structure and a contact electrode that aligns with the power supply electrode. When the cooling fan is inserted from the outside into the slot, the fan positioning structure engages with the housing positioning structure, thereby securing the fan in place and establishing an electrical connection between the contact electrode and the power supply electrode.

### FIELD OF THE INVENTION

The present invention relates to the technical field of power supply products for computer chassis, specifically referring to an installation method for a fan device of a power supply used in a computer chassis.

### BACKGROUND OF THE INVENTION

Currently, the power supply used in a computer chassis is an independent product, fixed inside the computer chassis by screws or other methods, and exposed on the rear side of the computer chassis. An external power cord plug is inserted into the socket of the chassis power supply to supply power to the chassis power supply, which then converts AC power into multiple DC power outputs for various components in the computer.

In order to dissipate heat from the chassis power supply, the current power supplies generally come with a fan device used to dissipate the heat generated by the power supply's operation. Most existing fan devices are integrated within the chassis power supply, making them relatively difficult to disassemble. After long-term use of the power supply, dust accumulation often leads to decreased fan speed or damage. At this point, the user typically can only replace the entire power supply. If the user attempts to repair the fan device themselves, they must first remove the power supply from the computer chassis, then disassemble the power supply to repair the fan device. Such operations are not only cumbersome but can also easily damage the power supply if not done carefully.

In response to the above problem, a relevant technical solution has been proposed in Chinese Utility Model Patent No. ZL03277733.7, which discloses a computer power supply with a separate cooling fan. Its technical solution is as follows: it includes a power supply body and a cooling fan installed inside the power supply body; along one exterior surface of the power supply body, an accommodating cavity is formed inwardly to house the cooling fan. On the inner wall of the accommodating cavity, there is an electrical connection device between the power supply body and the cooling fan. The cooling fan can be detachably installed in the accommodating cavity via a guiding device. In this technical solution, the cooling fan is separated from the power supply body, allowing it to be freely inserted and removed in the power supply, facilitating fan installation and removal by hand. However, its shortcoming is that because the cooling fan must be powered by the power supply body, there must be a corresponding electrical connection between the two. This solution uses a wire plug connection, which is inconvenient for installation or removal, and in the end still requires screws for fastening.

To solve this, the inventor of the present invention has made improvements, proposing the following technical solution.

### SUMMARY OF THE INVENTION

A first technical problem the present invention aims to solve is to overcome deficiencies in the prior art by providing a computer chassis power supply fan device that is easy to install and remove.

To address the aforementioned first technical problem, the present invention adopts the following technical solution: A fan device for a computer chassis power supply, comprising: a power supply housing, and a power supply body and a cooling fan installed in the power supply housing. The power supply housing has an outer side surface; said outer side surface is provided with a slot into which the cooling fan can be inserted and accommodated, and inside the slot there is a housing positioning structure and a power supply electrode electrically connected to the power supply body. The cooling fan comprises: a fan frame, fan blades pivotally connected to the fan frame, and a driving unit. The fan frame is provided with a fan positioning structure that mates with the housing positioning structure, and a contact electrode that corresponds to the power supply electrode. When the cooling fan is inserted into the slot from the outside inwards, once the fan positioning structure reaches the housing positioning structure, the mating between the fan positioning structure and the housing positioning structure positions the cooling fan in the slot, and in this state the power supply electrode and the contact electrode achieve electrical contact.

Furthermore, in the above technical solution, the power supply electrode and the contact electrode achieve electrical connection through elastic contact. That is, the power supply electrode or the contact electrode adopts an elastic metal probe.

Furthermore, in the above technical solution, the power supply electrode and the contact electrode achieve electrical connection through magnetic attraction, i.e., a magnet capable of mutual attraction is used in the power supply electrode and the contact electrode.

Furthermore, in the above technical solution, the housing positioning structure and the fan positioning structure adopt a snap-fit structure.

Furthermore, in the above technical solution, the housing positioning structure and the fan positioning structure adopt a magnetic attraction structure.

The power supply housing is a rectangular cuboid. The sheet metal on the left and right sides forms a cut portion, which, by being cut and bent inward, forms the slot. The cut portion includes: a baffle to define the side of the cooling fan, a support bar to support the cooling fan, and a limiting plate to define the height of the cooling fan.

Furthermore, in the above technical solution, air holes are provided on the top surface of the power supply housing; a wire-bundling hole is provided on the rear surface of the power supply housing.

Furthermore, in the above technical solution, a handle facilitating pulling is provided on the outside of the fan frame of the cooling fan.

Furthermore, in the above technical solution, the outer side surface of the power supply housing is provided with a power socket, a power switch, and evenly distributed small ventilation holes.

A second technical problem the present invention seeks to solve is to provide an installation method for a computer chassis power supply fan device that is simple to operate.

To address the aforementioned second technical problem, the present invention adopts the following technical solution: The installation method for a computer chassis power supply fan device is as follows. The power supply is installed on the computer chassis, and the outer side surface of the power supply is exposed on the chassis surface. A power socket is provided on the outer side surface. The power supply includes: a power supply housing and a power supply body and a cooling fan installed in the power supply housing. The installation method is as follows:

A slot is provided on the outer side surface of the power supply housing. The cooling fan is inserted into the power supply housing via the slot, and as the cooling fan is inserted from the outside in, a positioning structure between the cooling fan and the slot positions the cooling fan in the slot. Meanwhile, in this state, the contact electrode on the cooling fan and the power supply electrode provided on the power supply housing make electrical contact, allowing the power supply body inside the power supply to supply power to the cooling fan.

When needing to replace or clean the cooling fan, simply overcome the positioning connection between the cooling fan and the slot along the chassis surface where the slot is exposed, and pull the cooling fan out of the slot directly under external force.

After adopting the above technical solution, compared to the prior art, the present invention has the following beneficial effects:

The present invention independently arranges the cooling fan in the computer chassis power supply. A slot is directly provided on the outer side surface of the power supply housing, and the cooling fan is installed in the slot by a plugging fit. Because the slot is directly located on the outer side surface of the computer power supply housing, after the power supply is installed in the computer chassis, this outer side surface of the power supply housing is directly exposed on the surface of the computer chassis. The user can install or remove the cooling fan in the power supply without disassembling the computer chassis.

In order to facilitate removal and installation, the present invention does not use a conventional conductive connection by plug but instead directly provides a contact electrode on the cooling fan and a power supply electrode on the power supply housing. When the cooling fan is installed in the specified position, the contact electrode and the power supply electrode directly achieve electrical contact connection, thus achieving a power supply circuit connection without requiring an additional conductive plug connection.

In the present invention, in order to position the cooling fan, a positioning structure is set between the cooling fan and the slot to realize positioning of the cooling fan in the slot. This positioning structure may adopt magnetic attraction, elastic snap-fit, or other methods. These methods not only facilitate insertion and removal but also provide sufficient stability to ensure secure fan installation.

### BRIEF DESCRIPTION OF THE DRAWINGS

FIG. 1 is a perspective schematic diagram showing the present invention applied to a computer chassis;

FIG. 2 is an installation schematic diagram of the present invention;

FIG. 3 is a schematic diagram of the internal structure in a top-view state according to a first embodiment of the present invention;

FIG. 4 is a top view of the cooling fan in a second embodiment of the present invention;

FIG. 5 is a perspective view of a third embodiment of the present invention;

FIG. 6 is an exploded perspective view of the third embodiment of the present invention;

FIG. 7 is an exploded perspective view of the power supply housing in the third embodiment of the present invention.

### DETAILED DESCRIPTION OF THE EMBODIMENTS

Below, the present invention is further described in conjunction with specific embodiments and accompanying drawings.

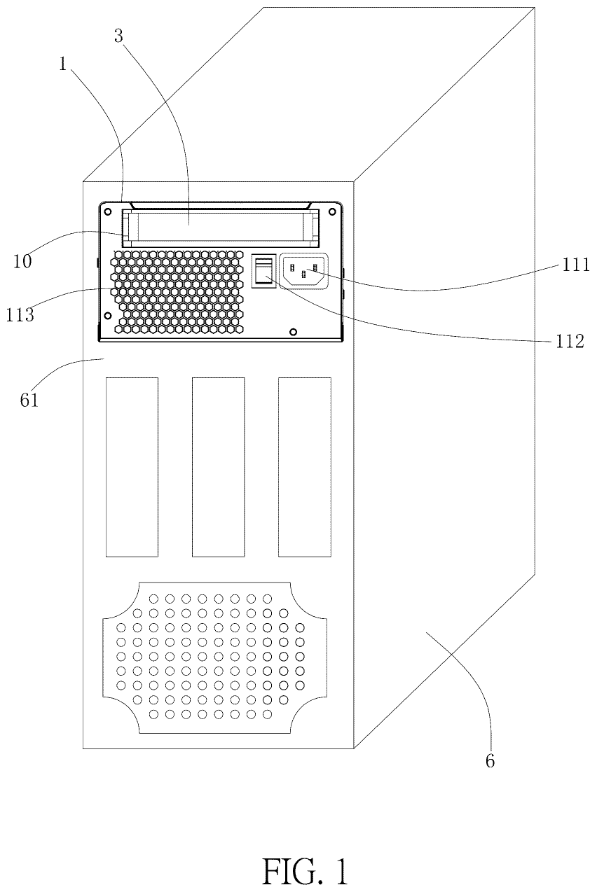

The present invention is a power supply used for a computer chassis. As shown in FIG. 1, a computer chassis 6 takes the shape of a rectangular cuboid, and the power supply 100 is installed in the chassis 6, with the outer side surface 11 of the power supply 100 directly exposed on the rear surface 61 of the chassis 6. This facilitates direct operation of the power supply 100. Typically, the outer side surface 11 of the power supply 100 is provided with a power plug 111, a power switch 112, and evenly distributed ventilation holes 113.

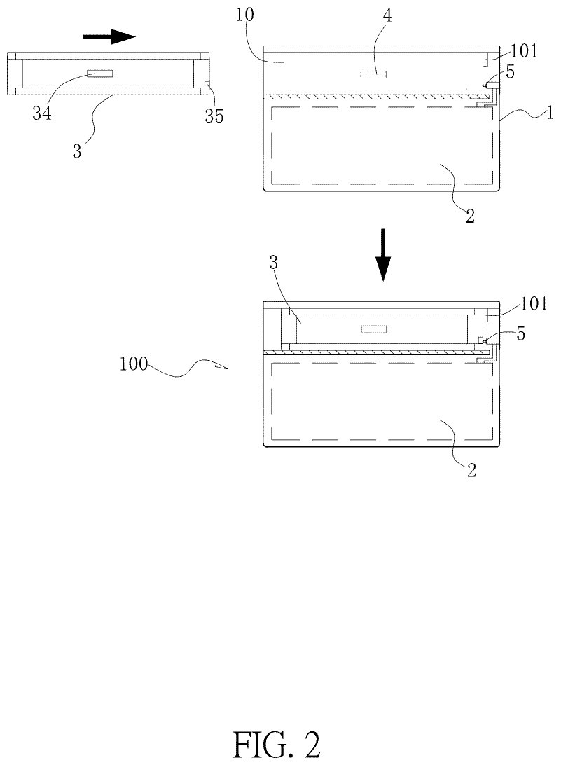

As shown in FIG. 2, the computer chassis power supply 100 comprises: a power supply housing 1 and a power supply body 2 and a cooling fan 3 installed in the power supply housing 1. In order to install and remove the cooling fan 3 without opening the chassis 6, the outer side surface 11 of the power supply housing 1 is provided with a slot 10 for insertion and accommodation of the cooling fan 3. Inside slot 10, a housing positioning structure 4 and a power supply electrode 5 (electrically connected to the power supply body 2) are provided.

The cooling fan 3 includes: a fan frame 31, fan blades 32 pivotally connected to the fan frame 31, and a driving unit 33. The fan frame 31 is provided with a fan positioning structure 34 that mates with the housing positioning structure 4, and a contact electrode 35 that corresponds to the power supply electrode 5.

The cross-sectional shape of the slot 10 matches the cross-sectional shape of the cooling fan 3, enabling the cooling fan 3 to be inserted along the slot 10. In order to position the cooling fan 3 relative to slot 10, a positioning structure is set between them. Specifically, the slot 10 is provided with the housing positioning structure 4, and the fan frame 31 is provided with the fan positioning structure 34 matching the housing positioning structure 4.

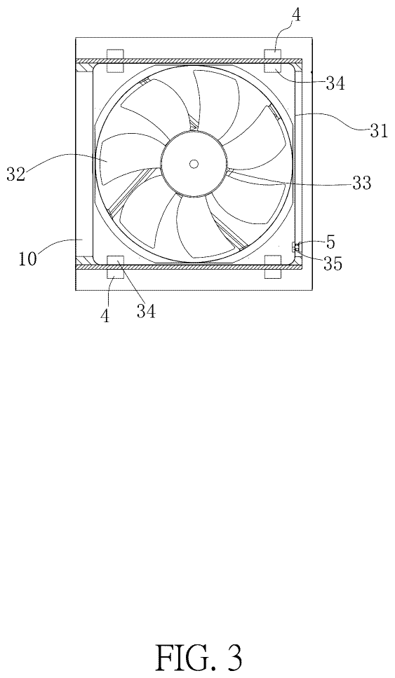

The housing positioning structure 4 and the fan positioning structure 34 may adopt the following positioning methods:
Method 1: Provide a protruding elastic snap on the sidewall of slot 10 as the housing positioning structure 4. The corresponding sidewall of the fan frame 31 is provided with a mating snap groove as the fan positioning structure 34, thereby achieving positioning between the cooling fan 3 and the slot 10 through the engagement of the elastic snap and the snap groove. For example, since the power supply housing 1 is generally made of metal sheet, the opposite left and right sheets of the power supply housing 1 may form a cut portion, which, after cutting and bending inward, forms the slot 10. A baffle used to define the side of the cooling fan 3 may be formed by stamping, producing a snap that uses the elasticity of the material itself for some elastic deformation. The fan frame 31 is typically formed by plastic injection molding, where the snap groove is integrally formed during molding. When the cooling fan 3 is inserted along slot 10 to the specified position, the snap will fall into the snap groove, forming a positional fit and thus fixing the cooling fan 3 in slot 10.
Method 2: The housing positioning structure 4 and the fan positioning structure 34 adopt a magnetic attraction positioning structure. In conjunction with FIG. 3, both sides of slot 10 are provided with a first magnet serving as the housing positioning structure 4, and the corresponding location on fan frame 31 is provided with a second magnet serving as the fan positioning structure 34. The first magnet and the corresponding second magnet produce a mutually attractive force. When the cooling fan 3 is inserted along slot 10 to the specified position, magnetic attraction between the first and second magnets fixes the cooling fan 3 in slot 10.

Additionally, as shown in FIG. 2, to prevent the cooling fan 3 from being inserted too far, the end of slot 10 is provided with a limiting structure 101. The limiting structure 101 can be a protruding stopper at the end of slot 10, which blocks the cooling fan 3 to prevent over-insertion and serves as a limit.

To electrically connect the cooling fan 3 with the power supply body 2 inside the power supply 100 so as to supply power to the cooling fan 3, the present invention employs the following approach: referring to FIGS. 2 and 3, the power supply housing 1 is provided with a power supply electrode 5, which is connected to the power supply body 2 by a wire. The cooling fan 3 is provided with a contact electrode 35, which is connected to the driving unit 33 by a wire. When the cooling fan 3 is fixed in slot 10, in that state, the power supply electrode 5 makes electrical contact with the contact electrode 35, thereby supplying power to the cooling fan 3 through the power supply body 2 inside the power supply 100.

The power supply electrode 5 and the contact electrode 35 may adopt the following connection methods:
Method 1: The power supply electrode 5 and the contact electrode 35 achieve electrical connection by elastic contact. For example, the power supply electrode 5 may be a commonly used elastic metal probe, while the contact electrode 35 is a metal conductor plate. When the cooling fan 3 is fixed in slot 10, the elastic metal probe serving as the power supply electrode 5 elastically presses against the metal conductor plate serving as the contact electrode 35, thereby realizing electrical connection.

Typically, the power supply electrode 5 is arranged on the inner side 14 of the power supply housing 1 opposite the outer side surface 11. The contact electrode 35 is arranged on the side of the fan frame 31 that is inserted into the slot. Of course, the power supply electrode 5 can also be arranged on the left (or right) sidewall of slot 10, and the contact electrode 35 can be arranged on the left (or right) side of the fan frame 31.

Method 2: The power supply electrode 5 and the contact electrode 35 adopt a magnetic attraction contact method to achieve electrical connection, i.e., the power supply electrode 5 and the contact electrode 35 use magnets that attract each other. The matching magnetic attraction ensures a stable connection between the power supply electrode 5 and the contact electrode 35.

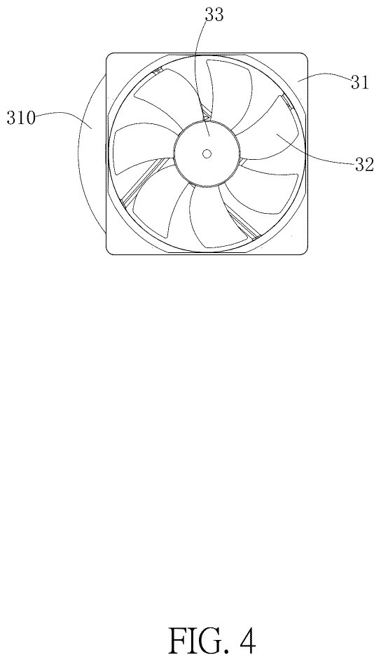

As shown in FIG. 4, in a second embodiment of the present invention, to facilitate the insertion and removal of the cooling fan 3, a handle 310 for easy pulling is arranged on the outer side of the fan frame 31 of the cooling fan 3. This handle 310 allows users to conveniently pull the cooling fan 3 out of slot 10.

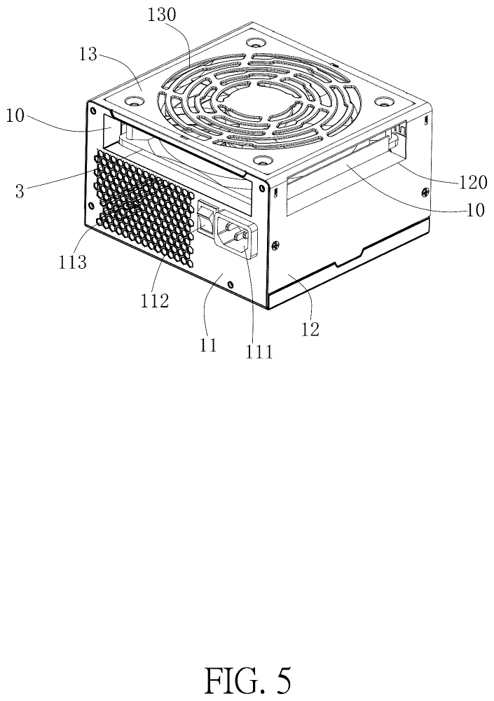

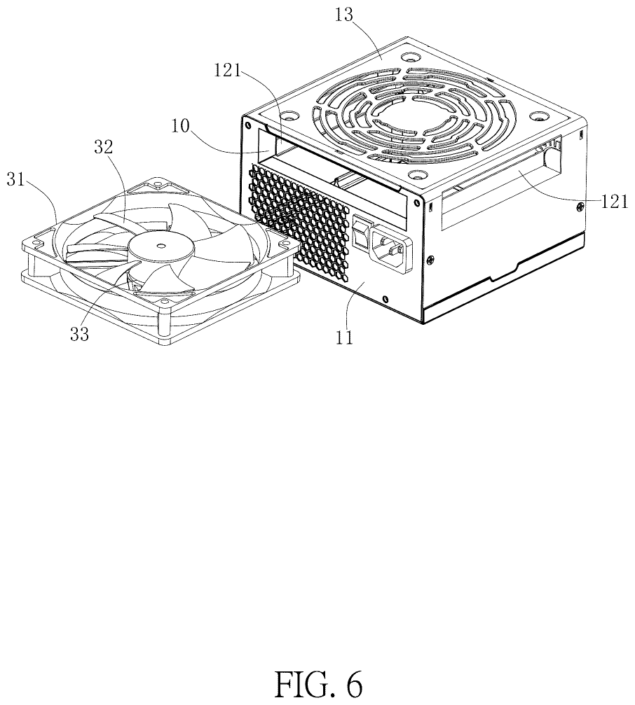

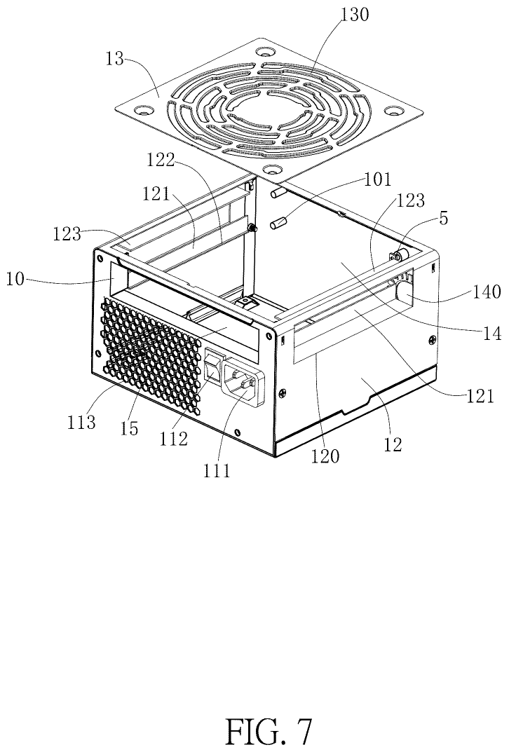

FIGS. 5 through 7 show a third embodiment of the present invention. The third embodiment is an actual application structure of the present invention. The power supply housing 1 is a rectangular cuboid, including an outer side surface 11, left and right side surfaces 12, a top surface 13, an inner side surface 14, and a bottom surface 15. These surfaces, made of metal sheets, enclose and form the power supply housing 1. Among them, the outer side surface 11 is provided with a through-hole that serves as the port of slot 10; on the outer side surface 11 are arranged a power socket 111, a power switch 112, and evenly distributed ventilation holes 113.

The sheet metal of the left side surface and the right side surface forms a cut portion 120, which, via cutting and bending inward, constitutes slot 10. Specifically, the cut portion 120 includes: a baffle 121 to define the side of the cooling fan 3, a support bar 122 to bear the weight of the cooling fan 3, and a limiting plate 123 to define the height of the cooling fan 3.

Air holes 130 are provided on the top surface 13 of the power supply housing, which correspond to the location of the fan blades 32 in the cooling fan 3 and facilitate airflow.

A wire-bundling hole 140 is provided on the rear side surface 14 of the power supply housing 1, through which the wire harness connected to the power supply body 2 can be extended to plug into various components inside the computer.

Referring to FIG. 1, the installation method of the third embodiment is as follows:

Install the entire power supply 100 onto the computer chassis 6, exposing the outer side surface 11 of the power supply 100 on the surface of the chassis 6.

Insert the cooling fan 3 into the power supply housing 1 through slot 10, and as the cooling fan 3 is inserted from the outside to the inside of slot 10, the positioning structure between the cooling fan 3 and slot 10 positions the cooling fan 3 in slot 10. Meanwhile, in this state, the contact electrode 35 on the cooling fan 3 makes electrical contact with the power supply electrode 5 on the power supply housing 1, thus supplying power to the cooling fan 3 through the power supply body 2 within the power supply 100.

When it is necessary to replace or clean the cooling fan 3, simply overcome the positioning connection between the cooling fan 3 and slot 10 from where the slot 10 is exposed on the surface of the computer chassis 6, and pull the cooling fan 3 directly out of slot 10 under external force.

The present invention has a simple structure and can realize quick replacement and maintenance of the power supply fan device.

Of course, the above is only a specific embodiment of the present invention and is not intended to limit the scope of the present invention. Any equivalent changes or modifications made based on the structures, features, and principles described in the claims of the present invention shall be included within the scope of the claimed patent of the present invention.

What is claimed is:

1. A fan device for a computer chassis power supply, the device comprising:
a power supply housing (1) having an outer side surface (11);
a power supply body (2) disposed within the power supply housing (1); and
a cooling fan (3) configured to be inserted into and accommodated within the power supply housing (1) through a slot (10) formed in the outer side surface (11), wherein:
the slot (10) includes a housing positioning structure (4) and a power supply electrode (5) electrically connected to the power supply body (2);
the cooling fan (3) comprises a fan frame (31), fan blades (32) pivotally connected to the fan frame (31), and a driving unit (33);
the fan frame (31) is provided with a fan positioning structure (34) corresponding to and engageable with the housing positioning structure (4), and a contact electrode (35) corresponding to the power supply electrode (5); and
when the cooling fan (3) is inserted from outside to inside through the slot (10), engagement between the fan positioning structure (34) and the housing positioning structure (4) secures the cooling fan (3) in the slot (10), and in this engaged state, the power supply electrode (5) and the contact electrode

(35) are in electrical contact.

2. The fan device of claim 1, wherein the power supply electrode (5) and the contact electrode (35) form an electrical connection via elastic contact, such that at least one of the power supply electrode (5) or the contact electrode (35) comprises an elastic metal probe.

3. The fan device of claim 1, wherein the power supply electrode (5) and the contact electrode (35) form an electrical connection via magnetic attraction, and wherein each of the power supply electrode (5) and the contact electrode (35) includes a magnet configured to attract one another.

4. The fan device of claim 1, wherein the housing positioning structure (4) and the fan positioning structure (34) comprise a snap-fit structure.

5. The fan device of claim 1, wherein the housing positioning structure (4) and the fan positioning structure (34) comprise a magnetic attraction structure.

6. The fan device of claim 1, wherein the power supply housing (1) is a rectangular cuboid, and wherein left and right side plates of the power supply housing (1) define a cut portion (120) that is bent inward to form the slot (10), the cut portion (120) including:
a baffle (121) configured to define a lateral boundary of the cooling fan (3);
a support bar (122) configured to support the cooling fan (3); and
a limiting plate (123) configured to define a vertical boundary of the cooling fan (3).

7. The fan device of claim 6, wherein:
the top surface (13) of the power supply housing (1) is provided with at least one vent hole (130); and
the rear surface (14) of the power supply housing (1) is provided with a wire-bundling hole (140).

8. The fan device of claim 1, wherein an exterior side of the fan frame (31) of the cooling fan (3) is provided with a handle (310) configured for pulling the cooling fan (3) out of the slot (10).

9. The fan device of claim 1, wherein the outer side surface (11) of the power supply housing (1) is provided with a power socket (111), a power switch (112), and a plurality of ventilation holes (113) distributed thereon.

10. A method of installing a fan device in a computer chassis power supply, the method comprising:
providing a computer chassis (6) having an exterior surface;
mounting a power supply (100) in the computer chassis (6) such that an outer side surface (11) of the power supply (100) is exposed at the exterior surface of the chassis (6), wherein the outer side surface (11) is formed with a slot (10), and wherein the power supply (100) includes a power supply body (2) within a power supply housing (1), a power supply electrode (5) electrically connected to the power supply body

(2) and a cooling fan (3) having a contact electrode (35);
inserting the cooling fan (3) into the slot (10) from outside to inside so that a positioning structure between the cooling fan (3) and the slot (10) secures the cooling fan (3) in place and causes the contact electrode (35) to form electrical contact with the power supply electrode (5), thereby allowing the power supply body (2) to power the cooling fan (3); and
removing the cooling fan (3) from the slot (10) by overcoming the positioning structure when replacement or cleaning of the cooling fan (3) is required.
